(19) United States
(12) Patent Application Publication
(10) Pub. No.: US 2024/0186968 A1
(43) Pub. Date: Jun. 6, 2024

(54) ANALOG OFFSET CANCELLATION CIRCUIT AND OPERATING METHOD

(71) Applicant: SAMSUNG ELECTRONICS CO., LTD., Suwon-si (KR)

(72) Inventors: TAIJI AN, SUWON-SI (KR); KYEONG-JOON KO, SUWON-SI (KR); HYOGYUEM RHEW, SUWON-SI (KR); BYOUNG JOO YOO, SUWON-SI (KR); DONGHYUK LIM, SUWON-SI (KR)

(21) Appl. No.: 18/202,732

(22) Filed: May 26, 2023

(30) Foreign Application Priority Data
Dec. 5, 2022 (KR) 10-2022-0168015

(51) Int. Cl. H03F 3/45

(52) U.S. Cl. CPC H03F 3/45475; H03F 2200/129; H03F 2200/375

(57) ABSTRACT

An offset cancellation circuit includes; a multi-stage amplifier including first and second amplifiers and configured to receive first and second input voltages and generate first and second output voltages, a comparator configured to compare the first and second output voltages, a digital to analog converter (DAC) configured to provide an offset cancellation voltage to the comparator during an offset cancellation operation for the comparator, and a feedback loop circuit configured to generate first and second control voltages in response to at least one DC level associated with the first and second output voltages and apply the first and second control voltages to the multi-stage amplifier to continuously cancel a DC offset of the multi-stage amplifier following the offset cancellation operation.

### CROSS-REFERENCE TO RELATED APPLICATIONS

This application claims priority under 35 U.S.C. § 119 to Korean Patent Application No. 10-2022-0168015 filed on Dec. 5, 2202 in the Korean Intellectual Property Office, the subject matter of which is hereby incorporated by reference in its entirety.

### BACKGROUND

Embodiments of the inventive concept relate to analog offset cancellation circuits. More particularly, embodiments of the inventive concept relate to analog offset cancellation circuits capable of canceling an offset voltage associated with high-speed multi-stage amplifier circuits, such as those used in wired communication receivers. Embodiments of the inventive concept also relate to operating methods for same.

In various applications such as receiver (RX) analog front ends (RXAFE) of high-speed interfaces (HSI), a multi-stage amplifier structure including small-gain amplifiers connected in multiple stages may be used to implement high-gain amplifiers operating at high speed. In such cases, an output of each stage amplifier has a DC offset due to mismatch(es) caused by variations in certain manufacturing process(es). The DC offset introduces errors in the post-processing of an output of the multi-stage amplifier and limits performance of the overall system.

To remove the output offset of the multi-stage amplifier, a digital offset calibration structure may be used. In this case, since the offset cancellation operation proceeds simultaneously in both the digital and analog domains, it is often difficult to perform verification through simulation. In addition, since calibration is performed before operation of the multi-stage amplifier, it may be difficult to compensate for offset fluctuations that change in real time.

### SUMMARY

Embodiments of the inventive concept provide analog offset cancellation circuits capable of canceling an offset voltage of a high-speed multi-stage amplifier circuit. Embodiments of the inventive concept also provide an operating method for same.

According to an embodiment of the inventive concept, an analog offset cancellation circuit may include: a multi-stage amplifier including first and second amplifiers and configured to receive first and second input voltages and generate first and second output voltages, a comparator configured to compare the first and second output voltages, a digital to analog converter (DAC) configured to provide an offset cancellation voltage to the comparator during an offset cancellation operation for the comparator, and a feedback loop circuit configured to generate first and second control voltages in response to at least one DC level associated with the first and second output voltages and apply the first and second control voltages to the multi-stage amplifier to continuously cancel a DC offset of the multi-stage amplifier following the offset cancellation operation.

According to an embodiment of the inventive concept, a method of operating an analog offset cancellation circuit for canceling a DC offset of a multi-stage amplifier may include: providing, by operation of a digital-to-analog converter (DAC), an offset cancellation voltage to a comparator during an offset cancellation operation for the comparator, and thereafter, performing, by operation of a feedback loop circuit, a continuous canceling of the DC offset of the multi-stage amplifier, wherein the performing of the continuous canceling of the DC offset of the multi-stage amplifier includes: receiving first and second output voltages generated by the multi-stage amplifier, generating first and second control voltages in response to the first and second output voltages, and providing the first and second control voltages to the multi-stage amplifier, such that DC levels of the first and second output voltages are the same.

According to an embodiment of the inventive concept a wired communication receiver receiving high-speed data may include: an offset cancellation circuit configured to receive the data from a channel, wherein the offset cancellation circuit includes: a multi-stage amplifier including first and second amplifiers and configured to receive first and second input signals and generate first and second output signals, a comparator configured to compare the first and second output voltages, a digital to analog converter (DAC) configured to provide an offset cancellation voltage to the comparator during an offset cancellation operation for the comparator, and a feedback loop circuit configured to generate first and second control voltages in response to at least one DC level associated with the first and second output voltages and apply the first and second control voltages to the multi-stage amplifier to continuously cancel a DC offset of the multi-stage amplifier following the offset cancellation operation.

### BRIEF DESCRIPTION OF THE DRAWINGS

Advantages, benefits and features, as well as the making and use of the inventive concept may be clearly understood upon consideration of the following detailed description together with the accompanying drawings, in which;

FIG. 1 is a circuit diagram illustrating an analog offset cancellation circuit according to embodiments of the inventive concept;

FIG. 2 is a circuit diagram further illustrating a multi-stage amplifier according to embodiments of the inventive concept;

FIG. 3 is a circuit diagram illustrating a second amplifier according to embodiments of the inventive concept;

FIG. 4 is a circuit diagram illustrating a feedback loop circuit according to embodiments of the inventive concept;

FIG. 5 is a flowchart illustrating an operating method for an analog offset cancellation circuit according to embodiments of the inventive concept;

FIG. 6 is a flowchart further illustrating in one example the offset cancellation operation for the comparator (S110) in the operating method of FIG. 5;

FIG. 7 is a flowchart further illustrating in one example the offset cancellation operation for the multi-stage amplifier (S120) in the operating method of FIG. 5;

FIG. 8 is a graph illustrating an offset cancellation operation of a multi-stage amplifier of an analog offset cancellation circuit according to embodiments of the inventive concept;

FIG. 9 is a circuit diagram illustrating, in part, an analog offset cancellation circuit according to embodiments of the inventive concept;

FIG. 10 is a circuit diagram illustrating a multi-stage amplifier according to embodiments of the inventive concept;

FIG. 11 is a circuit diagram illustrating a feedback loop circuit according to embodiments of the inventive concept;

FIG. 12 is a circuit diagram illustrating an analog offset cancellation circuit according to embodiments of the inventive concept; and

FIG. 13 is a block diagram illustrating a receiver according to embodiments of the inventive concept.

### DETAILED DESCRIPTION

Throughout the written description and drawings, like reference numbers and labels are used to denote like or similar elements, components, features and/or method steps.

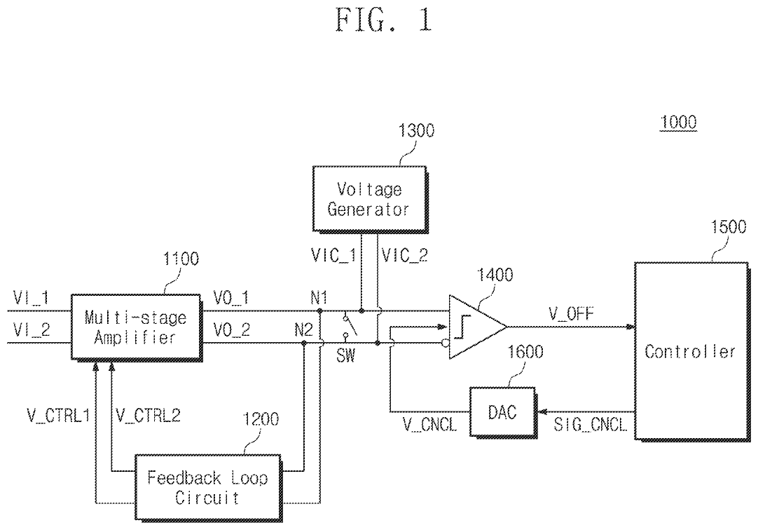

Figure (FIG. 1 is a circuit diagram illustrating an analog offset cancellation circuit 1000 according to embodiments of the inventive concept. Referring to FIG. 1, the analog offset cancellation circuit 1000 includes a multi-stage amplifier 1100, a feedback loop circuit 1200, a voltage generator 1300, a comparator 1400, a controller 1500, and a digital-to-analog converter (DAC) 1600.

The multi-stage amplifier 1100 includes a plurality of amplifiers configure to amplify various input voltage(s). The amplifiers may be connected in series, wherein an output voltage provide by a preceding amplifier may be applied as an input voltage to a succeeding amplifier. In this manner the input voltages may be serially and successively amplified. In relation to FIG. 1, it is assumed that the multi-stage amplifier 1100 amplifies first and second input voltages VI_1 and VI_2 to generate first and second output voltages VO_1 and VO_2.

The output voltages provided by the multi-stage amplifier 1100 may have a Direct Current (DC) offset (hereinafter, “offset”) due to various process mismatch(es). That is, the respective first and second output voltages VO_1 and VO_2 of the multi-stage amplifier 1100 may have different DC levels (e.g., a difference between common mode voltages generated in two signal paths).

The feedback loop circuit 1200 may receive the output voltages VO_1 and VO_2 of the multi-stage amplifier 1100 and may respectively generate first and second control voltages V_CTRL1 and V_CTRL2 in response to the first and second output voltages VO_1 and VO_2. For example, the feedback loop circuit 1200 may generate the first and second control voltages V_CTRL1 and V_CTRL2 in response to (or based on) a DC level difference between the first and second output voltages VO_1 and VO_2.

The feedback loop circuit 1200 may apply the first and second control voltages V_CTRL1 and V_CTRL2 to the multi-stage amplifier 1100 as feedback signals. During normal operation of the analog offset cancellation circuit 1000, the feedback loop circuit 1200 may apply the first and second control voltages V_CTRL1 and V_CTRL2 to the multi-stage amplifier 1100, such that the DC levels of the first and second output voltages VO_1 and VO_2 of the multi-stage amplifier 1100 are the same. That is, the feedback loop circuit 1200 may apply the first and second control voltages V_CTRL1 and V_CTRL2 to the multi-stage amplifier 1100 in order to adjust the first and second control voltages V_CTRL1 and V_CTRL2 in accordance with the DC level difference between the first and second output voltages VO_1 and VO_2 to continuously cancel the offset of the multi-stage amplifier 1100.

For example, the feedback loop circuit 1200 may reduce the DC level difference between the first and second control voltages V_CTRL1 and V_CTRL2 such that the DC levels of the first and second output voltages VO_1 and VO_2 are the same.

For example, the feedback loop circuit 1200 may generate the first and second control voltages V_CTRL1 and V_CTRL2 having the same DC level difference as the DC level difference between the first and second output voltages VO_1 and VO_2. The feedback loop circuit 1200 may apply the first and second control voltages V_CTRL1 and V_CTRL2 to the multi-stage amplifier 1200. That is, the feedback loop circuit 1200 may apply the first and second control voltages V_CTRL1 and V_CTRL2 having the same DC level difference as the DC level difference between the first and second output voltages VO_1 and VO_2, such that the DC levels of the first and second output voltages VO_1 and VO_2 are the same.

The feedback loop circuit 1200 may be designed with a sufficiently low bandwidth such that the high-speed signal of the multi-stage amplifier 1100 does not affect the DC levels of the signals. That is, the feedback loop circuit 1200 may have a sufficiently low bandwidth such that components other than DC components among the first and second output voltages VO_1 and VO_2 of the multi-stage amplifier 1100 are not passed. In this regard, the feedback loop circuit 1200 may be designed to operate as a low pass filter.

The voltage generator 1300 may generate various voltages necessary to the operation of the comparator 1400 and apply same to the comparator 1400. For example, the voltage generator 1300 may generate and apply first and second comparator input voltages VIC_1 and VIC_2 during an offset cancellation operation of the comparator 1400 performed by the analog offset cancellation circuit 1000.

The comparator 1400 may then generate a comparison voltage by comparing the first and second output voltages VO_1 and VO_2 of the multi-stage amplifier 1100 with one or more reference voltage(s) during normal operation of the analog offset cancellation circuit 1000. For example, the comparator 1400 may receive the first and second comparator input voltages VIC_1 and VIC_2 from the voltage generator 1300 during the offset cancellation operation of the comparator 1400 within the analog offset cancellation circuit 1000. The comparator 1400 may generate and provide an offset voltage V_OFF to the controller 1500 in response to, and least in part, the first and second comparator input voltages VIC_1 and VIC_2 and/or the first and second output voltages VO_1 and VO_2.

The controller 1500 may receive the offset voltage V_OFF from the comparator 1400 during the offset cancellation operation of the comparator 1400 within the analog offset cancellation circuit 1000. The controller 1500 may generate a cancellation signal SIG_CTRL in response to the offset voltage V_OFF received from the comparator 1400. The cancellation signal SIG_CNCL may be a signal causing the DAC 1600 to set an offset cancellation voltage V_CNCL. In this case, the controller 1500 may provide the cancellation signal SIG_CNCL to the DAC 1600.

The DAC 1600 may receive the cancellation signal SIG_CNCL during the offset cancellation operation of the comparator 1400 in the analog offset cancellation circuit 1000. That is, the DAC 1600 may set the offset cancellation voltage V_CNCL in response to the cancellation signal SIG_CNCL. Here, the offset cancellation voltage V_CNCL may be understood as a voltage that cancels the offset voltage V_OFF of the comparator 1400.

For example, the DAC 1600 may generate the offset cancellation voltage V_CNCL in response to the cancellation signal SIG_CNCL. The DAC 1600 may apply the generated offset cancellation voltage V_CNCL to the comparator 1400. As a result, the offset voltage V_OFF of the comparator 1400 may be canceled. The DAC 1600 may maintain the state of the offset cancellation voltage V_CNCL to continuously cancel the offset voltage V_OFF of the comparator 1400.

Thus, the DAC 1600 sets the offset cancellation voltage V_CNCL during the offset cancellation operation of the comparator 1400 within the analog offset cancellation circuit 1000 in order to effectively maintain a cancellation state in relation to the offset voltage V_OFF of the comparator 1400 during normal operation of the analog offset cancellation circuit 1000.

In this manner, the analog offset cancellation circuit 1000 may perform the offset cancellation operation of the comparator 1400, wherein the analog offset cancellation circuit 1000 need only once perform the offset cancellation operation of the comparator 1400 before beginning normal operation. During the offset cancellation operation of the comparator 1400 in the analog offset cancellation circuit 1000, a switch SW may be activated (e.g., turned ON). Alternately, the analog offset cancellation circuit 1000 may perform the offset cancellation operation of the multi-stage amplifier 1100, wherein the analog offset cancellation circuit 1000 may perform the offset cancellation operation of the multi-stage amplifier 1100 during normal operation. Here, during normal operation of the analog offset cancellation circuit 1000, the switch SW may be activated (e.g., turned OFF).

Accordingly, in some embodiments, after the providing, by operation of the DAC, of an offset cancellation voltage to the comparator during the offset cancellation operation for the comparator, and before the performing, by operation of the feedback loop circuit, of the continuous canceling of the DC offset of the multi-stage amplifier, a method of operating the analog offset cancellation circuit 1000 may include activating a switch SW disposed between (e.g.,) a first signal path passing the first output voltage to a first input of the comparator and a second signal path passing the second output voltage to a second input of the comparator.

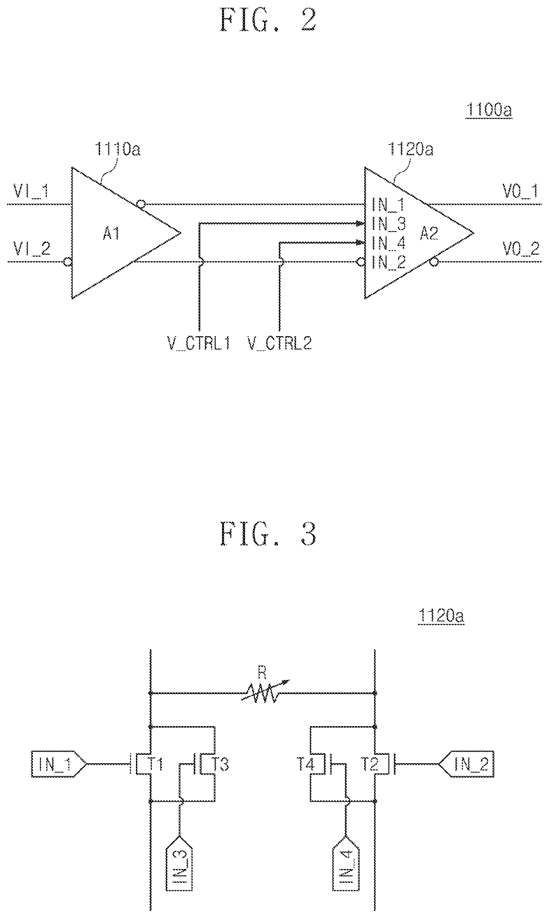

FIG. 2 is a circuit diagram illustrating a multi-stage amplifier 1100a according to embodiments of the inventive concept. Referring to FIGS. 1 and 2, the multi-stage amplifier 1100a may include a first amplifier A1 1110a and a second amplifier A2 1120a.

During normal operation of the analog offset cancellation circuit 1000, the multi-stage amplifier 1100a may amplify the first and second input voltages VI_1 and VI_2 in order to generate the first and second output voltages VO_1 and VO_2. That is, the first amplifier A1 1110a may receive and amplify the first and second input voltages VI_1 and VI_2 in order to generate corresponding voltage signals applied to a first terminal IN_1 and a second terminal IN_2 of the second amplifier A2 1120a. The second amplifier A2 1120a may then amplify the corresponding voltage signals received from the first amplifier A1 1110a in order to generate the first and second output voltages VO_1 and VO_2. Here, the first and second output voltages VO_1 and VO_2 may have an offset due to various process related mismatch(es) causing the respective DC levels of the first and second output voltages VO_1 and VO_2 to be different.

However, the feedback loop circuit 1200 may apply the first and second control voltages V_CTRL1 and V_CTRL2 to a third terminal IN_3 and a fourth terminal IN_4 of the second amplifier A2 1120a. Accordingly, during normal operation of the analog offset cancellation circuit 1000, the feedback loop circuit 1200 may apply the first and second control voltages V_CTRL1 and V_CTRL2 to the second amplifier A2 1120a through the third terminal IN_3 and the fourth terminal IN_4, such that the DC levels of the output voltages VO_1 and VO_2 of the multi-stage amplifier 1100a are the same. That is, the feedback loop circuit 1200 may apply the first and second control voltages V_CTRL1 and V_CTRL2 to the second amplifier A2 1120a in order to adjust the first and second control voltages V_CTRL1 and V_CTRL2 and equalize the DC levels of the first and second output voltages VO_1 and VO_2 of the multi-stage amplifier 1100a.

In this regard, the feedback loop circuit 1200 may apply the first and second control voltages V_CTRL1 and V_CTRL2 to the second amplifier A2 1120a to allow the voltages supplied from the first amplifier A1 1110a to the second amplifier A2 1120a to be adjusted. As a result of adjusting the voltages received by the second amplifier A2 1120a from the first amplifier A1 1110a, the DC levels of the first and second output voltages VO_1 and VO_2 of the multi-stage amplifier 1100a may be the same.

In the above-described embodiments, the feedback loop circuit 1200 may apply the first and second control voltages V_CTRL1 and V_CTRL2 to the second amplifier A2 1120a, and may adjust the first and second control voltages V_CTRL1 and V_CTRL2 depending on the DC level difference between the first and second output voltages VO_1 and VO_2 to continuously cancel the offset of the multi-stage amplifier 1100a.

FIG. 3 is a circuit diagram further illustrating in one example the second amplifier A2 1120a of FIG. 2 according to embodiments of the inventive concept. Referring to FIGS. 1, 2 and 3, the second amplifier A2 1120a may include the first, second, third and fourth (hereafter, “first to fourth”) terminals IN_1 to IN_4, a resistor R, and first to fourth transistors T1 to T4.

The first to fourth terminals IN_1 to IN_4 may be respectively connected to the first to fourth transistors T1 to T4. For example, the first terminal IN_1 may be connected to the first transistor T1, the second terminal IN_2 may be connected to the second transistor T2, the third terminal IN_3 may be connected to the third transistor T3, and the fourth terminal IN_4 may be connected to the fourth transistor T4.

The resistor R may be connected between the first terminal IN_1 and the second terminal IN_2, wherein the first transistor T1 is connected in parallel with the third transistor T3 and the second transistor T2 is connected in parallel with the fourth transistor T4.

The first to fourth transistors T1 to T4 may receive various voltages through the first to fourth terminals IN_1 to IN_4, respectively. For example, the first transistor T1 may receive one of the corresponding voltage signals provided by the first amplifier A1 1110a through the first terminal IN_1. The second transistor T2 may receive another one of the corresponding voltage signals provided by the first amplifier A1 1110a through the second terminal IN_2. The third transistor T3 may receive the first control voltage V_CTRL1 through the third terminal IN_3, and the fourth transistor T4 may receive the second control voltage V_CTRL2 through the fourth terminal IN_4.

During normal operation of the analog offset cancellation circuit 1000, the feedback loop circuit 1200 may apply the first and second control voltages V_CTRL1 and V_CTRL2 to the second amplifier A2 1120a, and may adjust the corresponding voltages signals provided by the first amplifier A1 1110a in relation to a DC level difference between the first and second output voltages VO_1 and VO_2, such that the DC levels of the first and second output voltages VO_1 and VO_2 of the multi-stage amplifier 1100a are the same.

The feedback loop circuit 1200 may apply the first control voltage V_CTRL1 to the second amplifier A2 1120a through the third terminal IN_3. When the second amplifier A2 1120a receives the first control voltage V_CTRL1, a DC channel of the third transistor T3 changes, and accordingly, a DC channel of the first transistor T1 may change. A sum of a change in current due to a change in the DC channel of the third transistor T3 and a change in current due to a change in the DC channel of the first transistor T1 may be effectively zero. That is, the current flowing through the first transistor T1 may decrease by as much as the current flowing through the third transistor T3 increases, and the current flowing through the first transistor T1 may increase by as much as the current flowing through the third transistor T3 decreases.

The feedback loop circuit 1200 may apply the second control voltage V_CTRL2 to the second amplifier A2 1120a through the fourth terminal IN_4. When the second amplifier A2 1120a receives the second control voltage V_CTRL2, a DC channel of the fourth transistor T4 changes, and accordingly, a DC channel of the second transistor T2 may change. A sum of a change in current due to a change in the DC channel of the fourth transistor T4 and a change in current due to a change in the DC channel of the second transistor T2 may be zero. That is, the current flowing through the second transistor T2 may decrease by as much as the current flowing through the fourth transistor T4 increases, and the current flowing through the second transistor T2 may increase by as much as the current flowing through the fourth transistor T4 decreases.

In response to changes in the DC channels of the first transistor T1 and the second transistor T2, the feedback loop circuit 1200 may adjust the corresponding voltage signals provided by the first amplifier A1 1110a to the second amplifier A2 1120a. For example, in response to a change in the DC channel of the first transistor T1, the feedback loop circuit 1200 may adjust a one corresponding voltage signal provided to the second amplifier A2 1120a through the first terminal IN_1, and in response to the change of the DC channel of the second transistor T2, the feedback loop circuit 1200 may adjust another voltage signal provided to the second amplifier A2 1120a through the second terminal IN_2.

By adjusting the corresponding voltage signals provided to the second amplifier A2 1120a from the first amplifier A1 1110a, the feedback loop circuit 1200 may allow the DC levels of the first and second output voltages VO_1 and VO_2 of the multi-stage amplifier 1100a to be the same.

In the above-described embodiments, the feedback loop circuit 1200 may apply the first and second control voltages V_CTRL1 and V_CTRL2 to the second amplifier A2 1120a, and may adjust the corresponding voltage signals depending on the DC level difference between the first and second output voltages VO_1 and VO_2 in order to continuously cancel the offset of the multi-stage amplifier 1100a.

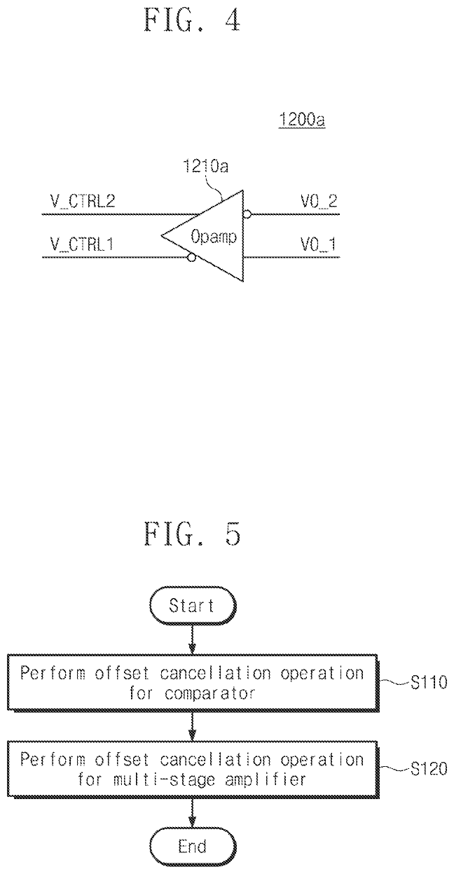

FIG. 4 is a circuit diagram further illustrating in one example (1200a) the feedback loop circuit 1200 of FIG. 1 according to embodiments of the inventive concept. Referring to FIGS. 1, 2, 3, and 4, the feedback loop circuit 1200a may be a negative feedback circuit including an operational amplifier Opamp 1210a.

The operational amplifier Opamp 1210a may receive the first and second output voltages VO_1 and VO_2 of the multi-stage amplifier 1100a. For example, the operational amplifier Opamp 1210a may be connected to two nodes N1 and N2 of the multi-stage amplifier 1100a to receive the first and second output voltages VO_1 and VO_2. In this case, the two nodes N1 and N2 may be short-circuited by a virtual grounding of the operational amplifier Opamp 1210a. Accordingly, the first and second output voltages VO_1 and VO_2 of the multi-stage amplifier 1100a may be passed to the operational amplifier Opamp 1210a without being passed to the comparator 1400.

The operational amplifier Opamp 1210a may be designed with a sufficiently low bandwidth such that the high-speed operating nature of the multi-stage amplifier 1100a does not affect the DC level of relevant signals (e.g., voltages). That is, the operational amplifier Opamp 1210a may have a sufficiently low bandwidth such that signal components other than the DC component among the first and second output voltages VO_1 and VO_2 of the multi-stage amplifier 1100a do not pass. In some embodiments, the operational amplifier Opamp 1210a may be designed to operate as a low pass filter.

The operational amplifier Opamp 1210a may be used to generate the first and second control voltages V_CTRL1 and V_CTRL2 in response to the first and second output voltages VO_1 and VO_2. For example, the operational amplifier Opamp 1210a may generate the first and second control voltages V_CTRL1 and V_CTRL2 in response to a DC level difference between the first and second output voltages VO_1 and VO_2.

The operational amplifier Opamp 1210a may apply the first and second control voltages V_CTRL1 and V_CTRL2 to the second amplifier A2 1120a through the third terminal IN_3 and the fourth terminal IN_4. During normal operation of the analog offset cancellation circuit 1000, the operational amplifier Opamp 1210a may apply the first and second control voltages V_CTRL1 and V_CTRL2 to the second amplifier A2 1120a, such that the DC levels of the first and second output voltages VO_1 and VO_2 provided by the second amplifier A2 1120a are the same. That is, the operational amplifier Opamp 1210a may apply the first and second control voltages V_CTRL1 and V_CTRL2 to the second amplifier A2 1120a, and may adjust the corresponding voltage signals depending on the DC level difference between the first and second output voltages VO_1 and VO_2 to continuously cancel the offset of the multi-stage amplifier 1100a.

FIG. 5 is a general flowchart illustrating an operating methods for the analog offset cancellation circuit according to embodiments of the inventive concept.

Referring to FIGS. 1 and 5, the operating method may include performing an offset cancellation operation of the comparator 1400 (S110). During the performing of the offset cancellation operation of the comparator 1400 (S110) by the analog offset cancellation circuit 1000, the DAC 1600 may provide (or set) the offset cancellation voltage V_CNCL to the comparator 1400. That is, the analog offset cancellation circuit 1000 may cancel the offset voltage V_OFF of the comparator 1400 by performing the offset cancellation operation of the comparator 1400. Here, the offset cancellation operation of the comparator 1400 may need to be performed only once before normal operation of the analog offset cancellation circuit 1000.

Referring to FIGS. 1 and 5, the operating method may further include performing an offset cancellation operation for the multi-stage amplifier 1100 during normal operation of the analog offset cancellation circuit 1000 (S120). That is, the analog offset cancellation circuit 1000 may cause the DC levels of the first and second output voltages VO_1 and VO_2 of the multi-stage amplifier 1100 to be the same by performing the offset cancellation operation of the multi-stage amplifier 1100 (S120). In this regard, the analog offset cancellation circuit 1000 may perform the offset cancellation operation of the multi-stage amplifier 1100 in order to continuously cancel the offset of the multi-stage amplifier 1100.

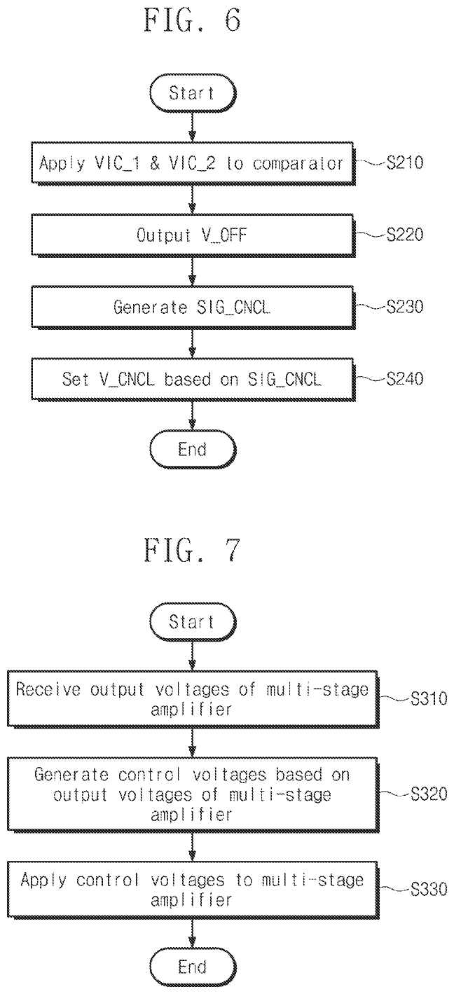

FIG. 6 is a flowchart further illustrating in one example the offset cancellation operation for the comparator 1400 (S110) of FIG. 5.

Referring to FIGS. 1, 5, and 6, during the offset cancellation operation for the comparator 1400 in the analog offset cancellation circuit 1000, the DAC 1600 may set the offset cancellation voltage V_CNCL to the comparator 1400. For example, the voltage generator 1300 may generate and apply the first and second comparator input voltages VIC_1 and VIC_2 to the comparator 1400 (S210).

In response, the comparator 1400 may provide the offset voltage V_OFF of the comparator 1400 (S220). For example, the comparator 1400 may output the offset voltage V_OFF of the comparator 1400 to the controller 1500 in response to the first and second comparator input voltages VIC_1 and VIC_2 received from the voltage generator 1300.

The controller 1500 may generate the cancellation signal SIG_CNCL (S230). For example, the controller 1500 may generate the cancellation signal SIG_CNCL in response to the offset voltage V_OFF, wherein the cancellation signal SIG_CNCL is a signal causing the DAC 1600 to set the offset cancellation voltage V_CNCL. In this case, the controller 1500 may provide the cancellation signal SIG_CNCL to the DAC 1600.

The DAC 1600 may then set the offset cancellation voltage V_CNCL in response to the cancellation signal SIG_CNCL received from the controller 1500 (S240). For example, the DAC 1600 may generate the offset cancellation voltage V_CNCL in response to the cancellation signal SIG_CNCL. The DAC 1600 may apply the generated offset cancellation voltage V_CNCL to the comparator 1400. The DAC 1600 may maintain the applied state of the offset cancellation voltage V_CNCL to continuously cancel the offset voltage V_OFF of the comparator 1400.

FIG. 7 is a flowchart further illustrating in one example the offset cancellation operation (S120) of the multi-stage amplifier 1100 of FIG. 5. Referring to FIGS. 1, 4, 5, and 7, the Opamp 1210a of the feedback loop circuit 1200a may receive the first and second output voltages VO_1 and VO_2 of the multi-stage amplifier 1100 (S310).

The operational amplifier Opamp 1210a may generate the first and second control voltages V_CTRL1 and V_CTRL2 in response to the first and second output voltages VO_1 and VO_2 (S320). The operational amplifier Opamp 1210a may generate the first and second control voltages V_CTRL1 and V_CTRL2 in response to the DC level difference between the first and second output voltages VO_1 and VO_2. For example, the operational amplifier Opamp 1210a may generate the first and second control voltages V_CTRL1 and V_CTRL2 having the same DC level difference as the DC level difference between the first and second output voltages VO_1 and VO_2.

The operational amplifier Opamp 1210a may apply the first and second control voltages V_CTRL1 and V_CTRL2 to the multi-stage amplifier 1100 (S330). The operational amplifier Opamp 1210a may cancel the offset of the multi-stage amplifier 1100 by applying the first and second control voltages V_CTRL1 and V_CTRL2. That is, as a result of applying the first and second control voltages V_CTRL1 and V_CTRL2, the DC levels of the first and second output voltages VO_1 and VO_2 of the multi-stage amplifier 1100 may become the same.

By repeatedly performing operations S310, S320 and S330, the analog offset cancellation circuit 1000 may continuously cancel the offset of the multi-stage amplifier 1100. That is, the analog offset cancellation circuit 1000 may continuously cancel the offset of the multi-stage amplifier 1100 when offset variation(s) associated with the multi-stage amplifier 1100 occur in accordance with the first and second input voltages VO_1 and VO_2, operating temperature, etc.

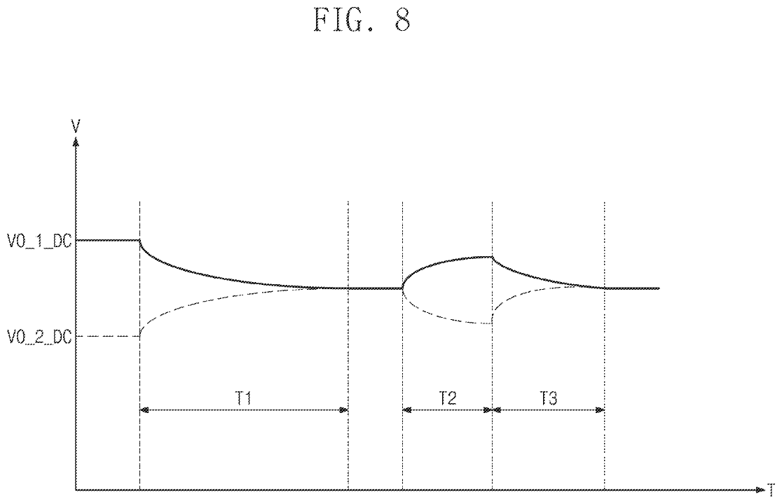

FIG. 8 is a graph illustrating an offset cancellation operation for the multi-stage amplifier 1100 of the analog offset cancellation circuit 1000 according to embodiments of the inventive concept. Referring to FIG. 8, the graph includes a horizontal axis indicating time (T), and a vertical axis indicating a DC level (V). Referring to FIGS. 1, 7, and 8, when a DC level VO_1_DC of the first output voltage VO_1 and a DC level VO_2_DC of the second output voltage VO_2 are different, the analog offset cancellation circuit 1000 may perform a first offset cancellation operation of the multi-stage amplifier 1100 during a first time interval T1. The analog offset cancellation circuit 1000 may perform the first offset cancellation operation of the multi-stage amplifier 1100 such that the DC level VO_1_DC of the first output voltage VO_1 and the DC level VO_2_DC of the second output voltage VO_2 are the same.

During a second time interval T2, the DC level VO_1_DC of the first output voltage VO_1 and the DC level VO_2_DC of the second output voltage VO_2 may be different. For example, the offset of the multi-stage amplifier 1100 may vary depending on the input voltages VO_1 and VO_2 or temperature.

When the DC level VO_1_DC of the first output voltage VO_1 and the DC level VO_2_DC of the second output voltage VO_2 are different, the analog offset cancellation circuit 1000 may perform the second offset cancellation operation of the multi-stage amplifier 1100 during a third time interval T3. The analog offset cancellation circuit 1000 may perform the second offset cancellation operation of the multi-stage amplifier 1100 such that the DC level VO_1_DC of the first output voltage VO_1 and the DC level VO_2_DC of the second output voltage VO_2 are the same.

Consistent with the foregoing, the analog offset cancellation circuit 1000 may continuously allow the DC levels VO_1_DC and VO_2_DC of the first and second output voltages VO_1 and VO_2 of the multi-stage amplifier 1100 to be the same.

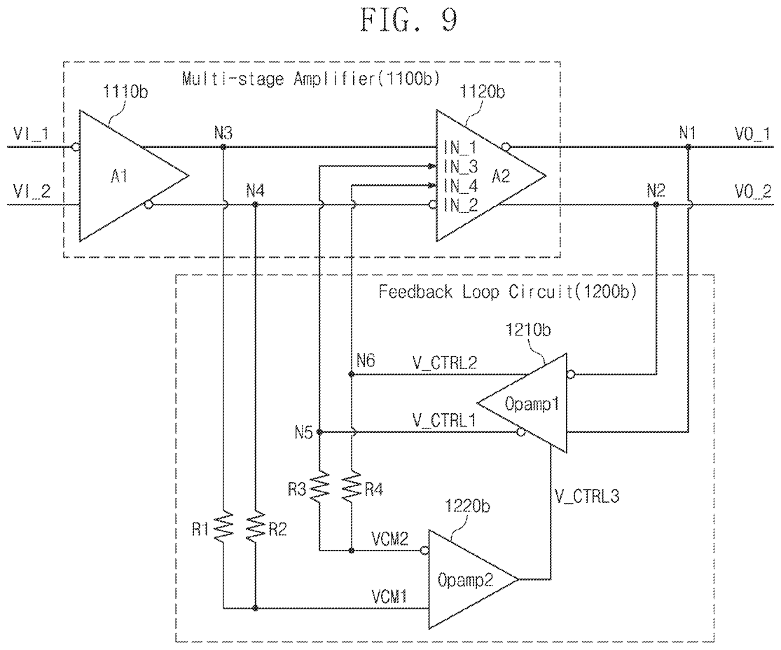

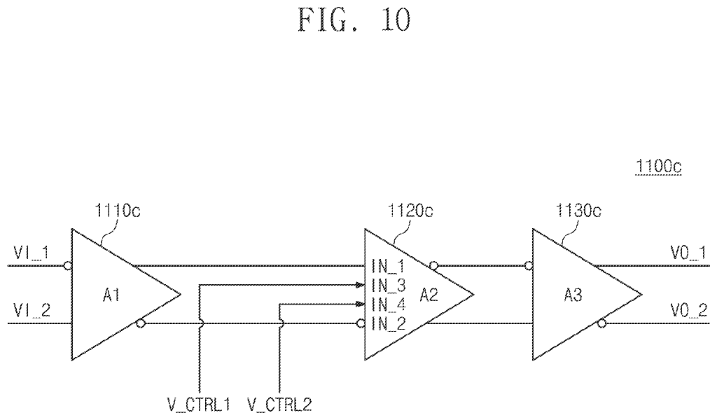

FIG. 9 is a circuit diagram illustrating, in part, the analog offset cancellation circuit 1000 according to embodiments of the inventive concept. Here, a multi-stage amplifier 1100b may be substantially similar to the multi-stage amplifier 1100a of FIG. 2.

Referring to FIGS. 1, 2, 3 and 9, a feedback loop circuit 1200b may include first to fourth resistors R1 to R4, a first operational amplifier Opamp1 1210b, and a second operational amplifier Opamp2 1220b. The feedback loop circuit 1200b may be a negative feedback circuit including the first operational amplifier Opamp1 1210b and the second operational amplifier Opamp2 1220b.

The feedback loop circuit 1200b may include the first to fourth resistors R1 to R4. The first to fourth resistors R1 to R4 may be connected to third to sixth nodes N3 to N6, respectively. For example, the first resistor R1 may be connected to the third node N3, the second resistor R2 may be connected to the fourth node N4, the third resistor R3 may be connected to the fifth node N5, and the fourth resistor R4 may be connected to the sixth node N6.

The first resistor R1 and the second resistor R2 may be connected to a seventh node N7, and the third resistor R3 and the fourth resistor R4 may be connected to an eighth node N8.

The first resistor R1 and the second resistor R2 may have the same resistance value, and the third resistor R3 and the fourth resistor R4 may have the same resistance value. Each of the first to fourth resistors R1 to R4 may have a resistance value of several tens of kΩ.

The first operational amplifier Opamp1 1210b may receive the first and second output voltages VO_1 and VO_2 of the multi-stage amplifier 1100. For example, the operational amplifier (Opamp) 1210 may be connected to the two nodes N1 and N2 of the multi-stage amplifier 1100 to receive the first and second output voltages VO_1 and VO_2.

The first operational amplifier Opamp1 1210b may generate the first and second control voltages V_CTRL1 and V_CTRL2 in response to the first and second output voltages VO_1 and VO_2. For example, the first operational amplifier Opamp1 1210b may generate the first and second control voltages V_CTRL1 and V_CTRL2 in response to the DC level difference between the first and second output voltages VO_1 and VO_2.

The first operational amplifier Opamp 1210b may apply the first and second control voltages V_CTRL1 and V_CTRL2 to the second operational amplifier A2 1120b through the third terminal IN_3 and the fourth terminal IN_4. During normal operation of the analog offset cancellation circuit 1000, the first operational amplifier Opamp 1210b may apply the first and second control voltages V_CTRL1 and V_CTRL2 to the second operational amplifier A2 1120b such that the DC levels of the first and second output voltages VO_1 and VO_2 of the second operational amplifier A2 1120b are the same. That is, the first operational amplifier Opamp 1210b may apply the first and second control voltages V_CTRL1 and V_CTRL2 to the second operational amplifier A2 1120b, and may adjust the first and second control voltages V_CTRL1 and V_CTRL2 depending on the DC level difference between the first and second output voltages VO_1 and VO_2 to continuously cancel the offset of the multi-stage amplifier 1100b.

The first operational amplifier Opamp1 1210b may receive a third control voltage V_CTRL3 from the second operational amplifier Opamp2 1220b. The first operational amplifier Opamp1 1210b may receive the third control voltage V_CTRL3 and may adjust the first and second control voltages V_CTRL1 and V_CTRL2, such that a first common mode voltage VCM1 and a second common mode voltage VCM2 are the same. In this case, the first common mode voltage VCM1 may be a common mode voltage of the first and second output voltages of the first amplifier A1 1110a, and the second common mode voltage VCM2 may be a common mode voltage of the first and second control voltages V_CTRL1 and V_CTRL2, which are the first and second output voltages of the first operational amplifier Opamp1 1210b.

The second operational amplifier Opamp2 1220b may be connected to the first resistor R1 and the second resistor R2 to receive the first common mode voltage VCM1. The second operational amplifier Opamp2 1220b may also be connected to the third resistor R3 and the fourth resistor R4 to receive the second common mode voltage VCM2.

The second operational amplifier Opamp2 1220b may compare the first common mode voltage VCM1 with the second common mode voltage VCM2 and generate the third control voltage V_CTRL3 in relation to the comparison result, and may then apply the third control voltage V_CTRL3 to the first operational amplifier Opamp1 1210b.

FIG. 10 is a circuit diagram illustrating a multi-stage amplifier 1100c according to embodiments of the inventive concept. Here, the second amplifier A2 1120c may be substantially similar to the second amplifier A2 1120a of FIG. 3.

Referring to FIGS. 1, 2, 3 and 10, the multi-stage amplifier 1100c may include the first amplifier A1 1110c, the second amplifier A2 1120c, and a third amplifier A3 1130c.

During normal operation of the analog offset cancellation circuit 1000, the multi-stage amplifier 1100c may be used to amplify the first and second input voltages VI_1 and VI_2 in order to generate the first and second output voltages VO_1 and VO_2. That is, the first amplifier A1 1110c may amplify the first and second input voltages VI_1 and VI_2 and pass the resulting (corresponding) first voltage signals to the second amplifier A2 1120c via the first terminal IN_1 and the second terminal IN_2. The second amplifier A2 1120c may then amplify the voltage signals provided by the first amplifier A1 1110c and pass the resulting second voltage signals to the third amplifier A3 1130c. The third amplifier A3 1130c may then amplify the corresponding second voltage signals provided by the second amplifier A2 1120c in order to generate the first and second output voltages VO_1 and VO_2. Here again, the first and second output voltages VO_1 and VO_2 may have an offset due to process-related mismatch(es). For example, the DC levels of the first and second output voltages VO_1 and VO_2 may be different.

The feedback loop circuit 1200 may apply the first and second control voltages V_CTRL1 and V_CTRL2 to the second amplifier A2 1120c through the third terminal IN_3 and the fourth terminal IN_4. During normal operation of the analog offset cancellation circuit 1000, the feedback loop circuit 1200 may apply the first and second control voltages V_CTRL1 and V_CTRL2 to the second amplifier A2 1120c through the third terminal IN_3 and the fourth terminal IN_4, such that the DC levels of the first and second output voltages VO_1 and VO_2 of the multi-stage amplifier 1100c are the same. That is, the feedback loop circuit 1200 may apply the first and second control voltages V_CTRL1 and V_CTRL2 to the second amplifier A2 1120c and may adjust the first and second control voltages V_CTRL1 and V_CTRL2 depending on the DC level difference between the first and second output voltages VO_1 and VO_2 to second voltage signals provided by the second amplifier A2 1120c. As a result of adjusting the voltage signals output by the second amplifier A2 1120c, the DC levels of the first and second output voltages VO_1 and VO_2 of the multi-stage amplifier 1100c may become the same.

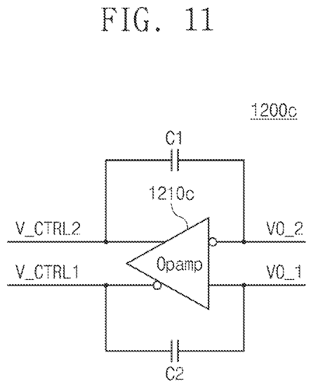

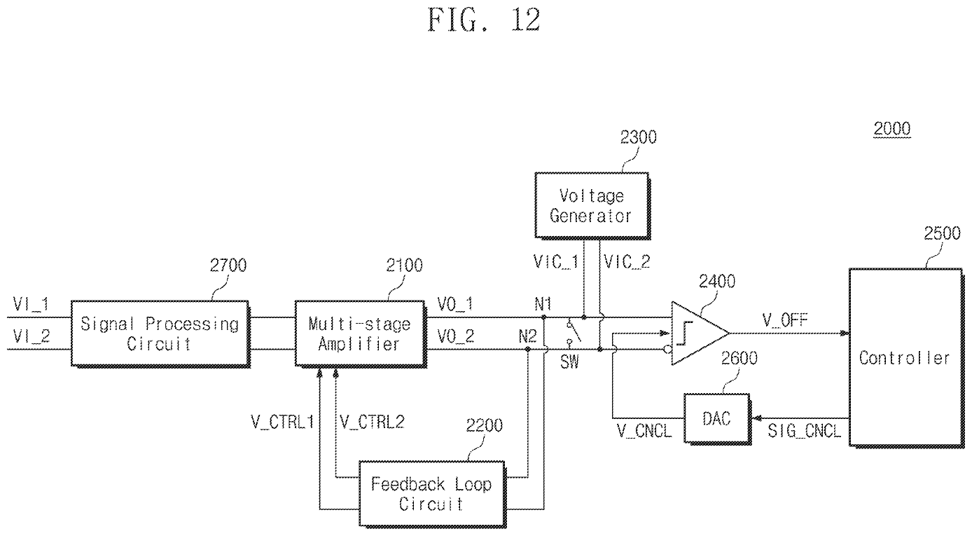

FIG. 11 is a circuit diagram illustrating a feedback loop circuit 1200c according to embodiments of the inventive concept. Referring to FIGS. 1, 4, and 11, the feedback loop circuit 1200c may include a plurality of capacitors (e.g., C1 and C2) and an operational amplifier Opamp 1210c.

The operational amplifier Opamp 1210c may be substantially similar to the operational amplifier(s) previously described in relation to FIG. 4.

The feedback loop circuit 1200c may be designed to have a sufficiently low bandwidth, such that the high-speed signal components of the multi-stage amplifier 1100 do not affect the DC level of the various voltage signals. That is, the operational amplifier Opamp 1210c may have a sufficiently low bandwidth, such that components other than the DC component among the first and second output voltages VO_1 and VO_2 of the multi-stage amplifier 1100 are not passed.

In some embodiments, the operational amplifier Opamp 1210c may operate as a low pass filter. For example, the feedback loop circuit 1200c may be a low pass filter including parallel-connected capacitors C1 and C2 and the operational amplifier Opamp 1210c. Those skilled in the art will appreciate that various low pass filter designs may be used to block undesired signal components. For example, various low pass filter designs may vary in a particular number, type, arrangement and capacitance value(s) of capacitors, as well as other circuit elements.

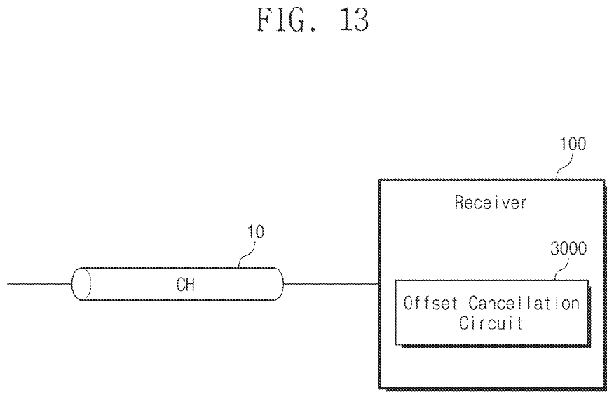

FIG. 12 is a circuit diagram illustrating an analog offset cancellation circuit 2000 according to embodiments of the inventive concept. Comparing FIGS. 1 and 12, the analog offset cancellation circuit 2000 may include a multi-stage amplifier 2100, a feedback loop circuit 2200, a comparator 2400, a controller 2500, and a digital-to-analog converter (DAC) 2600, and a signal processing circuit 2700. Here, the multi-stage amplifier 2100, the feedback loop circuit 2200, the comparator 2400, the controller 2500, and the DAC 2600 may be substantially and respectively similar to the multi-stage amplifier 1100, the feedback loop circuit 1200, the comparator 1400, the controller 1500, and the DAC 1600 of FIG. 1.

However, the signal processing circuit 2700 may additionally be provided to compensate for loss(es) associated with input voltages applied to the multi-stage amplifier 2100. For example, the signal processing circuit 2700 may compensate for loss(es) associated with the first and second input voltages VI_1 and VI_2 applied to the multi-stage amplifier 2100.

The signal processing circuit 2700 may vary by design in view of its purpose in compensating for loss(es) in various signals applied to the multi-stage amplifier 2100. For example, the signal processing circuit 2700 may be used to compensate for losses associated with parasitic capacitance(s) in the multi-stage amplifier 2100. Accordingly, some embodiments of the signal processing circuit 2700 may include at least one inductor and/or at least one resistor, such that input signals applied to the multi-stage amplifier 2100 exhibit acceptable power levels.

FIG. 13 is a general block diagram illustrating a receiver 100 according to embodiments of the inventive concept. Referring to FIG. 13, the receiver 100 may include an analog offset cancellation circuit 3000. Here, the analog offset cancellation circuit 3000 may be substantially similar to one or more of the embodiments previously described.

The receiver 100 may be a hardwired communication receiver configured to receive high-speed RX data. The receiver 100 may receive one or more signals through a channel (CH) 10. In this case, the channel 10 may be an electrical path connecting an external device (e.g., a transmitter) and the receiver 100, thereby enabling communication between the external device and the receiver 100. In some embodiments, the channel 10 may include a signal line or conductive trace associated with a printed circuit board (PCB) or a coaxial cable.

The analog offset cancellation circuit 3000 may serve as an analog front end receiving the high-speed RX data. The analog offset cancellation circuit 3000 may include a multi-stage amplifier structure capable of restoring losses in the high-speed RX data due to conditions of the channel 10. For example, the analog offset cancellation circuit 3000 may be designed to cancel offset(s) generated during operation of the multi-stage amplifier.

According to embodiments of the inventive concept, a DC offset of a multi-stage amplifier may fluctuate in real time, yet nonetheless be faithfully compensated for by use of an operational amplifier providing negative feedback.

According to embodiments of the inventive concept, the operational amplifier used in this regard may be implemented with a small offset, and given this attribute, the design and use of embodiments of the inventive concept are relatively easy, such that additional signal processing conventionally required to correct a DC offset is not required.

According to embodiments of the inventive concept, since the DC offset may be canceled using only an analog circuit, verification through simulation may be more readily facilitated.

The foregoing embodiments are presented as teaching examples. Those skilled in the art will appreciate that various modifications may be made to same without removing the resulting work from the scope of the inventive concept, as defined by the following claims.

What is claimed is:

1. An analog offset cancellation circuit comprising:
a multi-stage amplifier configured to receive first and second input voltages and generate first and second output voltages;
a comparator configured to compare the first and second output voltages;
a digital to analog converter (DAC) configured to provide an offset cancellation voltage to the comparator during an offset cancellation operation for the comparator; and
a feedback loop circuit configured to generate first and second control voltages in response to at least one DC level associated with the first and second output voltages and apply the first and second control voltages to the multi-stage amplifier to continuously cancel a DC offset of the multi-stage amplifier following the offset cancellation operation.

2. The analog offset cancellation circuit of claim 1, wherein the feedback loop circuit includes a first operational amplifier configured to receive the first and second output voltages and generate the first and second control voltages in response to the first and second output voltages.

3. The analog offset cancellation circuit of claim 2, wherein the feedback loop circuit is configured to receive the first and second output voltages in response to a virtual grounding of the first operational amplifier.

4. The analog offset cancellation circuit of claim 2, wherein the first operational amplifier is configured to generate the first and second control voltages in response to a DC level difference between the first and second output voltages.

5. The analog offset cancellation circuit of claim 4, wherein a DC level difference between the first and second control voltages, as generated by the feedback loop circuit, is the same as the DC level difference between the first and second output voltages.

6. The analog offset cancellation circuit of claim 2, wherein the first operational amplifier operates as a low pass filter.

7. The analog offset cancellation circuit of claim 1, wherein a first amplifier of the multi-stage amplifier is configured to receive the first and second input voltages, generate a first voltage signal and a second voltage signal, and provide the first voltage signal and the second voltage signal to a second amplifier of the multi-stage amplifier, and
the second amplifier is configured to receive the first voltage signal and the second voltage signal, receive the first and second control voltages from the feedback loop circuit, and adjust the first voltage signal and the second voltage signal, such that DC levels of the first and second output voltages are the same.

8. The analog offset cancellation circuit of claim 7, wherein the second amplifier includes a first transistor receiving the first voltage signal, a second transistor receiving the second voltage signal, a third transistor receiving the first control voltage and a fourth transistor receiving the second control voltage,
as a result of receiving the first control voltage, the first voltage signal provided to the first transistor is adjusted,
as a result of receiving the second control voltage, the second voltage signal provided to the second transistor is adjusted, and
as a result of adjusting the first voltage signal provided to the first transistor and adjusting the second voltage signal provided to the second transistor, DC levels of the first and second output voltages are the same.

9. The analog offset cancellation circuit of claim 8, wherein the feedback loop circuit includes:
a first operational amplifier configured to receive the first and second output voltages and generate the first and second control voltages in response to the first and second output voltages; and
a second operational amplifier configured to receive a first common mode voltage from the first amplifier, receive a second common mode voltage from the first operational amplifier, generate a third control voltage in response to the first common mode voltage and the second common mode voltage, provide the third control voltage to the first operational amplifier, and adjust the first and second control voltages, such that the first common mode voltage and the second common mode voltage are the same.

10. The analog offset cancellation circuit of claim 8, wherein the feedback loop circuit is configured to reduce a DC level difference between the first and second control voltages.

11. The analog offset cancellation circuit of claim 1, further comprising:
a signal processing circuit configured to compensate for loss in at least one of the first and second input voltages.

12. A method of operating an analog offset cancellation circuit for canceling a DC offset of a multi-stage amplifier, the method comprising:
providing, by operation of a digital-to-analog converter (DAC), an offset cancellation voltage to a comparator during an offset cancellation operation of the comparator; and thereafter,
performing, by operation of a feedback loop circuit, a continuous canceling of the DC offset of the multi-stage amplifier,
wherein the performing of the continuous canceling of the DC offset of the multi-stage amplifier includes receiving first and second output voltages generated by the multi-stage amplifier, generating first and second control voltages in response to the first and second output voltages, and providing the first and second control voltages to the multi-stage amplifier, such that DC levels of the first and second output voltages are the same.

13. The method of claim 12, wherein the first and second control voltages are generated further in response to a DC level difference between the first and second output voltages.

14. The method of claim 13, wherein a DC level difference between the first and second control voltages is the same as the DC level difference between the first and second output voltages.

15. The method of claim 12, wherein the providing, by operation of a digital-to-analog converter (DAC), of the offset cancellation voltage to the comparator during the offset cancellation operation of the comparator includes:
receiving in a controller, an offset voltage from the comparator;
generating, by operation of the controller, a cancellation signal in response to the offset voltage;
generating, by operation of the DAC, an offset cancellation voltage in response to the cancellation signal; and
providing the offset cancellation voltage from the DAC to the comparator.

16. The method of claim 12, wherein the operational amplifier operates as a low pass filter.

17. The method of claim 12, wherein the multi-stage amplifier includes:
a first amplifier configured to receive first and second input voltages, and generate corresponding voltage signals in response to the first and second input voltages; and
a second amplifier configured to receive the first and second control voltages and the corresponding voltage signals from the first amplifier, and generate the first and second output voltages in response to the first and second control voltages and the corresponding voltage signals,
wherein the corresponding voltage signals are adjusted by the second amplifier such that the DC levels of the first and second output voltages are the same.

18. The method of claim 12, wherein the multi-stage amplifier includes:
a first amplifier configured to receive first and second input voltages, and generate corresponding first voltage signals in response to the first and second input voltages;
a second amplifier configured to receive the first and second control voltages and the corresponding first voltage signals, adjust DC levels of the corresponding first voltage signals to be the same, and generate corresponding second voltage signals in response to the first and second control voltages and the adjusted corresponding first voltage signals; and
a third amplifier configured to receive the corresponding second voltage signals, and generate the first and second output voltages in response to the corresponding second voltage signals.

19. The method of claim 12, further comprising:
after the providing, by operation of the DAC, of an offset cancellation voltage to the comparator during the offset cancellation operation for the comparator, and before the performing, by operation of the feedback loop circuit, of the continuous canceling of the DC offset of the multi-stage amplifier, activating a switch between a first signal path passing the first output voltage to a first input of the comparator and a second signal path passing the second output voltage to a second input of the comparator.

20. A wired communication receiver receiving high-speed data and comprising:
an offset cancellation circuit configured to receive the data from a channel,
wherein the offset cancellation circuit includes:
a multi-stage amplifier including first and second amplifiers, configured to receive first and second input signals, and further configured to generate first and second output signals;
a comparator configured to compare the first and second output voltages;
a digital to analog converter (DAC) configured to provide an offset cancellation voltage to the comparator during an offset cancellation operation for the comparator; and
a feedback loop circuit configured to generate first and second control voltages in response to at least one DC level associated with the first and second output voltages and apply the first and second control voltages to the multi-stage amplifier to continuously cancel a DC offset of the multi-stage amplifier following the offset cancellation operation.
